(19) United States
(12) Patent Application Publication
(10) Pub. No.: US 2025/0142837 A1
(43) Pub. Date: May 1, 2025

(54) STRUCTURES HAVING 1T1R ARCHITECTURE FOR RESISTIVE RANDOM-ACCESS MEMORY DEVICES

(71) Applicant: GlobalFoundries Singapore Pte. Ltd., Singapore (SG)

(72) Inventors: XINSHU CAI, Singapore (SG); SHYUE SENG TAN, Singapore (SG)

(21) Appl. No.: 18/496,809

(22) Filed: Oct. 27, 2023

(51) Int. Cl. H10B 63/00; H10N 70/00

(52) U.S. Cl. CPC H10B 63/30; H10N 70/023; H10N 70/063; H10N 70/841

(57) ABSTRACT

The embodiments herein relate to structures having 1T1R architecture for RRAM devices and methods of forming the same. A structure for a memory device is provided. The structure includes a memory cell and a transistor. The memory cell includes a first electrode and a second electrode. The transistor is adjacent to the memory cell. The transistor includes a gate electrode including an upper section and a lower section, a third electrode under the gate electrode, and the second electrode, wherein the second electrode is above the third electrode and laterally adjacent to the lower section of the gate electrode.

### TECHNICAL FIELD

The present disclosure relates generally to memory devices, and more particularly to structures having 1T1R architecture for resistive random-access memory (RRAM) devices and methods of forming the same.

### BACKGROUND

One of the non-volatile memory (NVM) technologies utilized in advanced computing systems, like processing-in-memory (PIM) applications and machine learning (ML) applications, is a resistive random-access memory (RRAM) device that has one transistor-one resistor (1T1R) architecture. The RRAM device may make use of binary neural network (BNN)-based techniques to provide a high-density architecture with high parallel programming speed and low power consumption for advanced computing systems.

The 1T1R architecture of the RRAM device may include a single transistor (1T) coupled with a single RRAM cell (1R) in a crossbar three-dimensional (3D) configuration. The RRAM cell may utilize a resistive element to store data by changing its resistance states, representing binary values (0s and 1s), and the transistor may serve as an access element to read and write data to the RRAM cell.

In order to meet the growing needs of the semiconductor industry, structures having 1T1R architecture for resistive random-access memory (RRAM) devices providing for improved performance metrics and methods of forming the same are needed.

### SUMMARY

To achieve the foregoing and other aspects of the present disclosure, structures having 1T1R architecture for resistive random-access memory (RRAM) devices and methods of forming the same are presented.

According to an aspect of the present disclosure, a structure for a memory device is provided. The structure includes a memory cell and a transistor. The memory cell includes a first electrode and a second electrode. The transistor is adjacent to the memory cell. The transistor includes a gate electrode including an upper section and a lower section, a third electrode under the gate electrode, and the second electrode, wherein the second electrode is above the third electrode and laterally adjacent to the lower section of the gate electrode.

According to another aspect of the present disclosure, a structure for a memory device is provided. The structure includes an interlayer dielectric, a first memory cell, and a first transistor. The first memory cell is over the interlayer dielectric and the first transistor is partially in the interlayer dielectric. The first transistor includes a first electrode, a second electrode, and a gate electrode. The first electrode is in the interlayer dielectric and the second electrode is on the interlayer dielectric. The second electrode is a common electrode shared between the first transistor and the first memory cell. The gate electrode is partially in the interlayer dielectric and includes an upper section and a lower section. The second electrode is partially under the upper section of the gate electrode.

According to yet another aspect of the present disclosure, a method of forming a structure for a memory device is provided. The method includes forming an interlayer dielectric and forming a first electrode in the interlayer dielectric. A second electrode is formed on the interlayer dielectric. A gate electrode and a third electrode are formed partially in and on the interlayer dielectric, respectively. The gate electrode and the third electrode partially overlap the second electrode.

### BRIEF DESCRIPTION OF THE DRAWINGS

The embodiments of the present disclosure will be better understood from a reading of the following detailed description, taken in conjunction with the accompanying drawings:

FIG. 1A is a cross-sectional view of an RRAM device and FIG. 1B is a perspective view of a lower portion of the RRAM device in FIG. 1A, according to an embodiment of the disclosure.

FIGS. 2A to 2C are cross-sectional views of the RRAM device in FIG. 1A, illustrating a processing method of forming the same, according to an embodiment of the disclosure.

FIG. 3 is a cross-sectional view of an RRAM device, according to another embodiment of the disclosure.

FIG. 4 is a cross-sectional view of an RRAM device, according to yet another embodiment of the disclosure.

FIG. 5 is a cross-sectional view of an RRAM device, according to a further embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure.

Additionally, features in the drawings are not necessarily drawn to scale. For example, the dimensions of some of the features in the drawings may be exaggerated relative to other features to help improve the understanding of the embodiments of the device. The same reference numerals in different drawings denote the same features, while similar reference numerals may, but do not necessarily, denote similar features.

### DETAILED DESCRIPTION

The present disclosure relates to structures having one transistor-one resistor (1T1R) architecture for resistive random-access memory (RRAM) devices and methods of forming the same. Various embodiments of the present disclosure are now described in detail with accompanying drawings. It is noted that like and corresponding features are referred to by the use of the same reference numerals. The embodiments disclosed herein are exemplary, and not intended to be exhaustive or limiting to the disclosure.

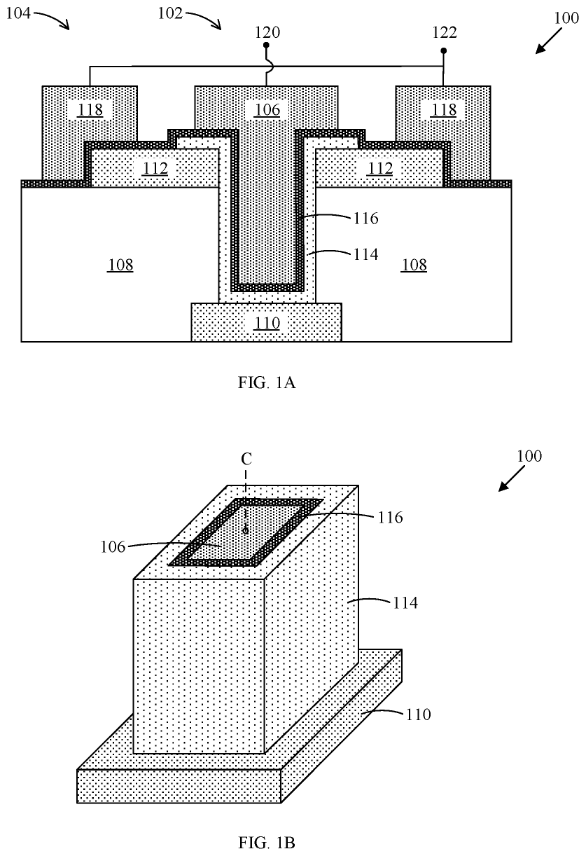

FIG. 1A illustrates a cross-sectional view of a structure 100 for an RRAM device and FIG. 1B illustrates a perspective view of a lower portion of the structure 100 in FIG. 1A, according to an embodiment of the disclosure. The structure 100 may be arranged in a memory region and the memory region may be arranged in a back-end-of-line (BEOL) region of a semiconductor device. The structure 100 may include a transistor 102 and a memory cell 104 coupled with the transistor 102. In this embodiment, the structure 100 may include one (1) bit cell having a 1T1R architecture and may be referred to as a 1T1R-RRAM device.

The transistor 102 may be partially in an interlayer dielectric (ILD) 108 and the memory cell 104 may be over the ILD 108. The transistor 102 may include a gate electrode 106. The gate electrode 106 may include an upper section that is predominantly horizontal and a lower section that is predominantly vertical adjoining the upper section. For example, the gate electrode 106 may adopt a T-shaped structure. The lower section of the gate electrode 106 may include a lower portion in the ILD 108 and an upper portion above the ILD 108, and the upper portion may adjoin the upper section of the gate electrode 106. Alternatively, the gate electrode 106 may adopt a planar structure that is predominantly vertical, and the planar structure may include a lower portion in the ILD 108 and an upper portion above the ILD 108. The gate electrode 106 may include an electrically conductive material, for example, tantalum, hafnium, titanium, copper, silver, cobalt, or tungsten. Alternatively, the gate electrode 106 may include a combination of electrically conductive materials, for example, titanium and titanium nitride. The ILD 108 may include an electrically insulative material, for example, silicon oxide, carbon-doped silicon oxide, tetraethoxysilane (TEOS), borophosphosilicate glass (BPSG), or undoped silicate glass (USG).

The transistor 102 may further include an electrode 110 and an electrode 112. The electrode 110 and the electrode 112 may serve as source/drain electrodes of the transistor 102. As used herein, the term “source/drain electrode” may refer to an electrically conductive element that can function as either a source or a drain of a transistor. For example, the electrode 110 may function as a source and the electrode 112 may function as a drain of the transistor 102, or vice versa.

The electrode 110 may be arranged in the ILD 108 under the gate electrode 106 and the electrode 112 may be arranged on the ILD 108. The electrode 112 may be further arranged partially under the upper section of the gate electrode 106. For example, the upper section of the gate electrode 106 may partially overlap a corner of the electrode 112. Even though FIG. 1A appears to illustrate the electrode 112 as two discrete structures, the two discrete structures may be integrally connected into or out of the page of the accompanying drawings and extend to opposite sides of the gate electrode 106 to function as a single electrode 112. Alternatively, the electrode 112 need not extend to opposite sides of the gate electrode 106 and may be arranged at either side of the gate electrode 106, even though this embodiment is not illustrated in the accompanying drawings. The electrode 110 and the electrode 112 may include an electrically conductive material, for example, ruthenium, platinum, titanium nitride, or tantalum nitride, though not necessarily the same electrically conductive material as each other. Additionally, the electrically conductive material of the electrode 110 may or may not include the same electrically conductive material as the gate electrode 106.

The transistor 102 may yet further include a channel layer 114 and a dielectric layer 116 over the channel layer 114. The channel layer 114 may serve as a pathway for charge carriers to move between the electrode 110 and the electrode 112. The dielectric layer 116 may serve as a gate dielectric layer of the transistor 102. The channel layer 114 and the dielectric layer 116 may be conformal and continuous, including a lower portion in the ILD 108 and an upper portion above the ILD 108. The channel layer 114 and the dielectric layer 116 may separate the electrode 110 and the electrode 112 from the gate electrode 106.

The channel layer 114 may be at least completely under the gate electrode 106. The channel layer 114 may overlap at least a portion of the electrode 110, and further extend vertically to partially overlap the electrode 112. For example, the channel layer 114 may include end portions terminating over an upper surface of the electrode 112. The end portions of the channel layer 114 may laterally extend beyond the gate electrode 106, as illustrated. Alternatively, the channel layer 114 may be under the gate electrode 106 such that a side surface of the upper section of the gate electrode 106 may be substantially coplanar with a side surface of the channel layer 114 (not shown). The channel layer 114 may include an oxide semiconductor material, for example, zinc oxide, cadmium oxide, indium oxide, or indium gallium zinc oxide. Alternatively, the channel layer 114 may include amorphous silicon.

The dielectric layer 116 may at least overlap the channel layer 114 under the gate electrode 106. The dielectric layer 116 may further overlap the electrode 112. For example, the dielectric layer 116 may directly overlap a remaining portion of the electrode 112 not covered by the channel layer 114, and further directly overlap a side surface of the electrode 112 distal from the gate electrode 106. The dielectric layer 116 may additionally extend to overlie the ILD 108. The dielectric layer 116 may include an electrically insulative material, for example, tantalum oxide, titanium oxide, hafnium oxide, aluminum oxide, or silicon oxide.

Referring to FIG. 1B, the lower section of the gate electrode 106 may be at least laterally enclosed by the lower portion of the channel layer 114 and the lower portion of the dielectric layer 116. Specifically, the lower portion of the dielectric layer 116 may surround four sides of the lower section and the lower surface of the gate electrode 106 (see FIG. 1A). The lower portion of the channel layer 114 may surround four sides of the lower portion of the dielectric layer 116, as well as the lower surface of the dielectric layer 116 (see FIG. 1A) such that the lower portion of the dielectric layer 116 is enclosed between the lower portion of the channel layer 114 and the lower section of the gate electrode 106. As a result, the lower section of the gate electrode 106, the lower portion of the dielectric layer 116, and the lower portion of the channel layer 114 may be concentric having a common center point C.

Referring back to FIG. 1A, the memory cell 104 may be arranged adjacent to the transistor 102 such that the electrode 112 may serve as a common electrode shared between the transistor 102 and the memory cell 104, i.e., the electrode 112 may serve as a source/drain electrode of the transistor 102 and also as a memory electrode of the memory cell 104.

The memory cell 104 may further include another memory electrode 118 over the ILD 108. In particular, the memory electrode 118 may be arranged laterally adjacent to the gate electrode 106 and partially overlap a corner of the electrode 112 that is distal from the gate electrode 106. Even though FIG. 1A appears to illustrate the memory electrode 118 as two discrete structures, the two discrete structures may be directly connected into or out of the page of the accompanying drawings and extend to opposite sides of the gate electrode 106 to function as a single memory electrode. The memory electrode 118 may include an electrically conductive material, for example, tantalum, hafnium, titanium, copper, silver, cobalt, or tungsten. Alternatively, the memory electrode 118 may include a combination of electrically conductive materials, for example, titanium and titanium nitride. It may be appreciated that the memory electrode 118 may include the same electrically conductive material as the gate electrode 106 of the transistor 102 for ease of fabrication. However, the memory electrode 118 and the gate electrode 106 may include different electrically conductive materials.

The dielectric layer 116 may additionally separate the memory electrode 118 from the electrode 112 and may serve as a common dielectric layer shared between the transistor 102 and the memory cell 104, i.e., the dielectric layer 116 may serve as a gate dielectric layer of the transistor 102 and also as a resistive layer of the memory cell 104.

Arranging the memory electrode 118 over the corner of the electrode 112 may advantageously improve the electrical performance of the memory cell 104. For example, the memory electrode 118 may overlap the corner of the electrode 112 where stronger electric fields may concentrate, and these higher electric fields may readily facilitate a pathway for the formation of one or more conductive filaments within the dielectric layer 116 to program the memory cell 104. The formation of one or more conductive filaments may be substantially confined in the region of the dielectric layer 116 around the corner of the electrode 112, thereby minimizing the variability of locations where the conductive filaments may form, as well as providing improved process stability.

The transistor 102 may serve as an access transistor to drive the memory cell 104. The structure 100 may be operated by electrically coupling the gate electrode 106 to one terminal 120 and the memory electrode 118 to another terminal 122. By applying appropriate electrical signals to the terminals 120, 122, the structure 100 may be operated. Moreover, when the transistor 102 is positioned in a BEOL region, the wiring between the memory cell 104 and the transistor 102 may be shortened. This leads to a decrease in the latency in the programming speed of the structure 100.

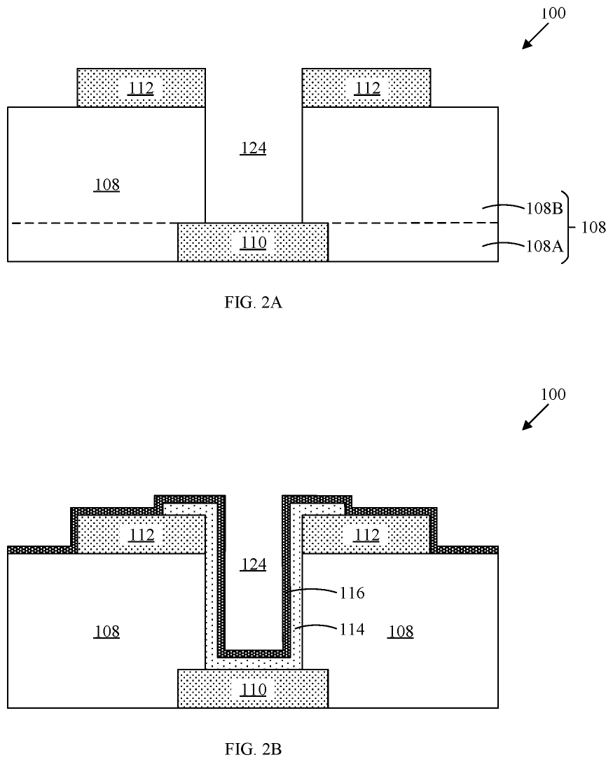

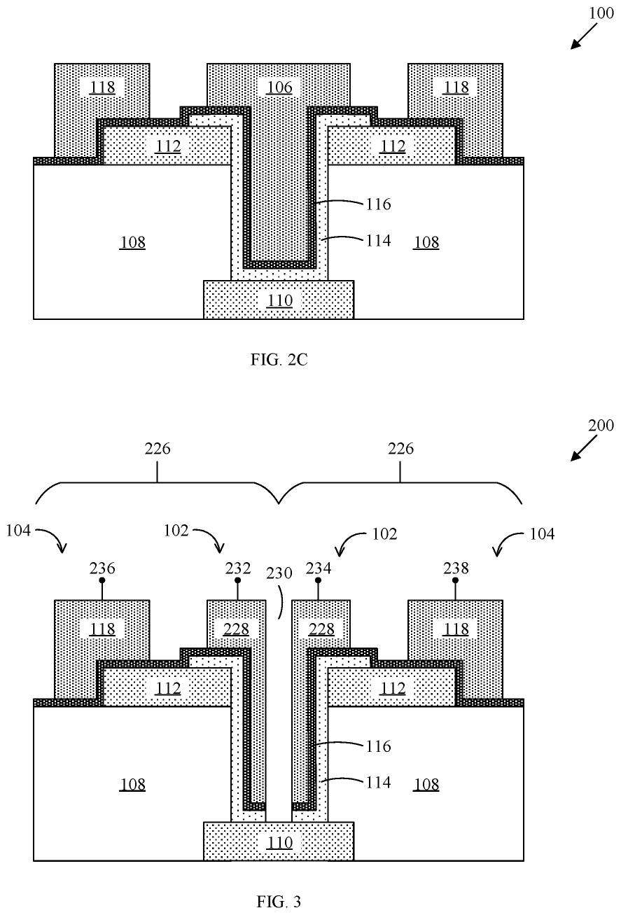

FIGS. 2A to 2C are cross-sectional views of the structure 100 in FIG. 1A, illustrating a processing method of forming the same, according to an embodiment of the disclosure. Certain structures may be fabricated, for example, using known processes and techniques, and specifically disclosed processes and methods may be used to achieve individual aspects of the present disclosure. The below-described order for the method of forming the structure 100 is intended to be illustrative, and the method is not limited to the specifically described order unless otherwise specifically stated.

As used herein, “deposition techniques” refer to the process of applying a material over another material. Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD).

Additionally, “patterning techniques” include deposition of material or photoresist, patterning, exposure, development, etching, cleaning, and/or removal of the material or photoresist as required in forming a described pattern, structure, or opening. Exemplary examples of techniques for patterning include, but not limited to, wet etch photolithographic processes, dry etch photolithographic processes, or direct patterning processes.

FIG. 2A illustrates a cross-sectional view of an intermediary structure of the structure 100 including the electrode 110 within the ILD 108 and the electrode 112 over the ILD 108. The electrode 110 may be formed by a patterning technique, including lithography and etching processes. For example, an electrically conductive material may be deposited using a deposition technique, including a CVD process, and subsequently patterned using the patterning technique. The ILD 108 may be formed over the electrode 110 using a deposition technique, including a CVD process. Alternatively, the electrically conductive material may be deposited within an opening of a first dielectric portion 108A and a planarizing technique, including a chemical-mechanical planarization process, may be subsequently performed to form the electrode 110. A second dielectric portion 108B may be deposited over the first dielectric portion 108A and the electrode 110. The first dielectric portion 108A and the second dielectric portion 108B may collectively form the ILD 108.

Another layer of electrically conductive material may be formed over the ILD 108 using a deposition technique, including a CVD process. The electrically conductive material may be subsequently patterned using a patterning technique, including lithography and etching processes, to form the electrode 112. Even though the electrode 112 may appear as two discrete structures in FIG. 2A, the two discrete structures may be formed from a single layer of electrically conductive material and may be directly connected into or out of the page of the accompanying drawings to function as a single electrode 112. An opening 124 may be formed in the ILD 108 to expose a portion of the electrode 110. The opening 124 may be formed by a patterning technique, including lithography and etching processes.

FIG. 2B illustrates the cross-sectional view of the structure 100 after forming the channel layer 114 and the dielectric layer 116 over the channel layer 114. The channel layer 114 may be formed by depositing an oxide semiconductor material or amorphous silicon using a deposition technique, including a CVD process, and subsequently patterned using a patterning technique, including lithography and etching processes. The channel layer 114 may be conformal and continuous, at least lining the opening 124. The channel layer 114 may further partially overlap a portion of the electrode 112, for example, the channel layer 114 may include end portions terminating on the upper surface of the electrode 112.

The dielectric layer 116 may be formed over the channel layer 114 by depositing an electrically insulative material using a deposition technique, including a CVD process, and subsequently patterned using a patterning technique, including lithography and etching processes. The dielectric layer 116 may be conformal and continuous, and may at least overlap the channel layer 114 and the electrode 112.

FIG. 2C illustrates a cross-sectional view of the structure 100 after forming the gate electrode 106 and the memory electrode 118. The gate electrode 106 and the memory electrode 118 may be formed of the same electrically conductive material for ease of fabrication. The electrically conductive material may be deposited over the dielectric layer 116 to at least overfill the opening 124. The electrically conductive material may be deposited using a deposition technique, including a CVD process or a PVD process. The electrically conductive material may be patterned using a patterning technique, including lithography and etching processes, to form the gate electrode 106 and the memory electrode 118 concurrently, each having an upper surface substantially coplanar with each other. The gate electrode 106 may include an upper section partially overlapping the electrode 112 and a lower section extending downward from the upper section. Alternatively, the gate electrode 106 and the memory electrode 118 may be formed separately in different fabrication process steps, which may result in the upper surfaces of the gate electrode 106 and the memory electrode 118 being substantially coplanar, or at an offset, with each other.

The memory electrode 118 may be laterally adjacent to the gate electrode 106 and at least over the distal corner of the electrode 112 from the gate electrode 106. Even though the memory electrode 118 may appear as two discrete structures in FIG. 2C, the two discrete structures may be formed from a single layer of electrically conductive material and may be directly connected into or out of the page of the accompanying drawings to function as a single memory electrode 118. In the embodiment where the gate electrode 106 and the memory electrode 118 are formed of different conductive materials, one or more deposition and patterning techniques may be required to form the gate electrode 106 and the memory electrode 118 separately in different fabrication process steps.

Processing continues with forming terminals electrically connected to the gate electrode 106 and the memory electrode 118 to provide electrical signals for the operation of the structure 100. The terminals may be synonymous with the terminals 120, 122 in FIG. 1A.

FIG. 3 is a cross-sectional view of a structure 200, according to another embodiment of the disclosure. The structure 200 may be similar to the structure 100 in FIG. 1A, and thus common features are labeled with the same reference numerals.

The structure 200 may include two (2) bit cells 226 each having a 1T1R architecture. Each bit cell 226 may include a transistor 102 and a memory cell 104. Each transistor 102 may include a gate electrode 228, an electrode 110, and an electrode 112. The gate electrodes 228 may be partially in an ILD 108. The gate electrodes 228 and the electrodes 112 of the transistors 102 may be separated and electrically isolated from each other.

An exemplary method of forming the gate electrodes 228 may include forming an opening 230 through an electrically conductive material, such as the gate electrode 106 in FIG. 1A, to form the gate electrode 228 for each transistor 102 where the gate electrodes 228 are electrically isolated from each other. The opening 230 may further extend through a dielectric layer 116 and a channel layer 114 such that the dielectric layer 116 and the channel layer 114 may be discontinuous to form each bit cell 226. A portion of the electrode 110 may be exposed in the opening 230. The opening 230 may additionally extend through the electrode 112 in FIG. 1A to form electrically isolated electrodes 112 for the transistors 102. The opening 230 may be formed using a patterning technique, including lithography and etching processes, and subsequently filled with a dielectric material.

Additionally, the gate electrodes 228 may be electrically coupled to terminals 232, 234 to drive their corresponding RRAM cells 104 in their respective bit cells 226. Similarly, the memory electrodes 118 may be separated and electrically isolated from each other, and electrically coupled to terminals 236, 238, serving as memory cells 104 of the structure 200. In an embodiment of the disclosure, the structure 200 may have a mirror symmetry through the opening 230 and the electrode 110.

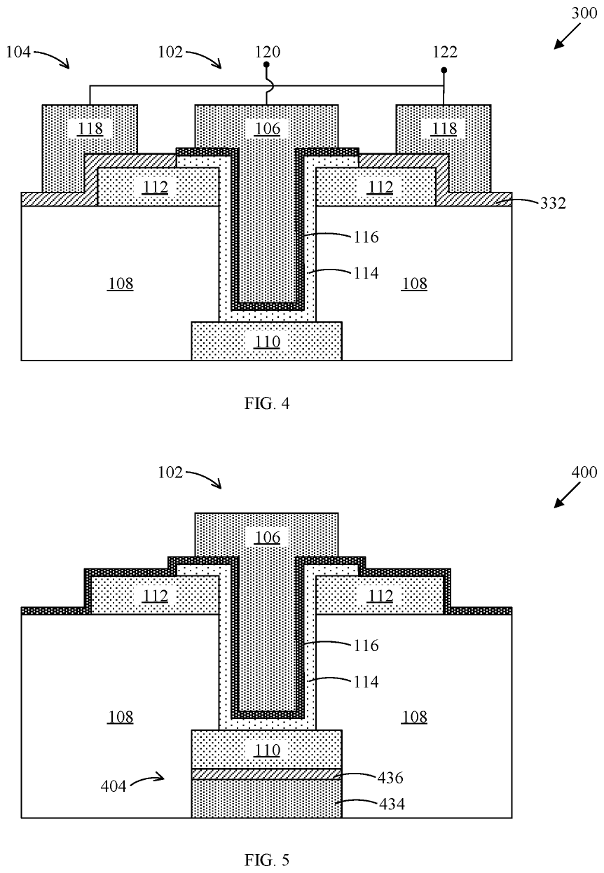

FIG. 4 is a cross-sectional view of a structure 300, according to yet another embodiment of the disclosure. The structure 300 may be similar to the structure 100 in FIG. 1A, and thus common features are labeled with the same reference numerals.

The structure 300 has a 1T1R architecture that includes a transistor 102 and a memory cell 104. Unlike the structure 100 in FIG. 1A where the dielectric layer 116 serves as a common dielectric layer for the transistor 102 and the memory cell 104, the structure 300 may have a resistive layer 332 specific to the memory cell 104, leaving the dielectric layer 116 specific to the transistor 102. The resistive layer 332 may partially overlap the memory electrode 112, and further overlap a side surface of the memory electrode 112 distal from the gate electrode 106. The resistive layer 332 may or may not adjoin the channel layer 114 and/or the dielectric layer 116, despite what is illustrated in FIG. 4.

In this embodiment, the material and thickness of the resistive layer 332 may vary depending on the design and process requirements of the structure 300. For example, the material of the resistive layer 332 need not necessarily include the same electrically insulative material as the dielectric layer 116, and the thickness of the resistive layer 332 may be thicker or thinner than the collective thickness of the dielectric layer 116 and the channel layer 114, even though the resistive layer 332 is illustrated to be thinner. The resistive layer 332 may include an electrically insulative material, for example, tantalum oxide, titanium oxide, hafnium oxide, aluminum oxide, or silicon oxide. The resistive layer 332 may be formed before or after the formation of the channel layer 114 and the dielectric layer 116 using a deposition technique, including a CVD process, and subsequently patterned using a patterning technique, including lithography and etching processes.

FIG. 5 is a cross-sectional view of a structure 400, according to yet another embodiment of the disclosure. The structure 400 may be similar to the structure 100 in FIG. 1A, and thus common features are labeled with the same reference numerals.

The structure 400 has a 1T1R architecture that includes a transistor 102 and a memory cell 404. Unlike the structure 100 in FIG. 1A where the memory cell 104 may be arranged over the ILD 108, the memory cell 404 may be arranged in the ILD 108 under the gate electrode 106. The memory cell 404 may include an electrode 110 that serves as a common electrode shared between the transistor 102 and the memory cell 404. The memory cell 404 may further include a memory electrode 434 under the electrode 110 and a resistive layer 436 between the electrode 110 and the memory electrode 434.

The memory electrode 434 and the resistive layer 436 may be formed by a multi-step process. An exemplary method of forming the memory electrode 434 and the resistive layer 436 is described herein. An electrically conductive material may be deposited using a deposition technique, including a CVD process, and subsequently patterned using a patterning technique, including lithography and etching processes, to form the memory electrode 434. Thereafter, an electrically insulative material may be deposited using a deposition technique, including a CVD process, and subsequently patterned using a patterning technique, including lithography and etching processes, to form the resistive layer 436. The electrode 110 may be formed using similar processes as that of the memory electrode 434. The ILD 108 may be formed during or after forming the memory cell 404 using a deposition technique, including a CVD process.

Alternatively, the electrically conductive material of the memory electrode 434, the electrically insulative material of the resistive layer 436, and the electrically conductive material of the electrode 110 may be sequentially deposited using a deposition technique and a patterning technique may be performed to form the memory electrode 434, the resistive layer 436, and the electrode 110 concurrently.

The electrode 110, the resistive layer 436, and the memory electrode 434 may include similar widths between their respective side surfaces. For example, the side surfaces of the electrode 110, the resistive layer 436, and the memory electrode 434 may be substantially coplanar with each other on opposite sides of the memory cell 404.

As presented above, various embodiments of structures having 1T1R architecture for RRAM devices and methods of forming the same are presented. The RRAM devices may be arranged in a BEOL area of a semiconductor device and may include at least one bit cell having a transistor coupled to an RRAM cell. The RRAM device may include a common conductive element shared between the transistor and the RRAM cell as a transistor electrode and a memory electrode, respectively. The transistor may be an access transistor to drive the RRAM cell, and the RRAM cell may be capable of forming localized conductive links in a resistive layer between two memory electrodes. At least one electrode may include a corner and the corner may advantageously improve the device performance and reduce the device-to-device variability by substantially confining the formation of the conductive link to a region in the dielectric liner subjected to relatively stronger electrical fields.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed by interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,” or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it being understood that various changes may be made in the function and arrangement of features and methods of fabrication described in an exemplary embodiment without departing from the scope of this disclosure as set forth in the appended claims.

What is claimed is:

1. A structure for a memory device, comprising:
a memory cell, the memory cell comprising a first electrode and a second electrode; and
a transistor adjacent to the memory cell, the transistor comprising a gate electrode including an upper section and a lower section, a third electrode under the gate electrode, and the second electrode, wherein the second electrode is above the third electrode and laterally adjacent to the lower section of the gate electrode.

2. The structure of claim 1, wherein the second electrode is partially under the upper section of the gate electrode.

3. The structure of claim 1, further comprising an interlayer dielectric, wherein the lower section of the gate electrode comprises a lower portion in the interlayer dielectric and an upper portion above the interlayer dielectric.

4. The structure of claim 3, wherein the third electrode is arranged in the interlayer dielectric and the second electrode is arranged on the interlayer dielectric.

5. The structure of claim 1, wherein the first electrode partially overlaps a corner of the second electrode distal from the gate electrode.

6. The structure of claim 1, wherein the transistor further comprises:
a channel layer partially overlapping the second electrode; and
a dielectric layer over the channel layer, wherein the channel layer and the dielectric layer are concentric around the lower section of the gate electrode.

7. The structure of claim 6, wherein the memory cell further comprises the dielectric layer between the first electrode and the second electrode.

8. The structure of claim 7, wherein the dielectric layer is a resistive layer of the memory cell.

9. The structure of claim 6, wherein the memory cell further comprises a resistive layer between the first electrode and the second electrode, wherein the resistive layer comprises a different material from the dielectric layer.

10. The structure of claim 9, wherein the resistive layer overlaps a remaining portion of the second electrode not covered by the channel layer.

11. The structure of claim 1, wherein the second electrode extends to opposite sides of the gate electrode.

12. A structure for a memory device, comprising:
an interlayer dielectric;
a first memory cell over the interlayer dielectric; and
a first transistor partially in the interlayer dielectric, the first transistor comprises:
a first electrode in the interlayer dielectric;
a second electrode on the interlayer dielectric, wherein the second electrode is a common electrode shared between the first transistor and the first memory cell; and
a gate electrode partially in the interlayer dielectric, the gate electrode including an upper section and a lower section, wherein the second electrode is partially under the upper section of the gate electrode.

13. The structure of claim 12, further comprising:
a second transistor adjacent to the first transistor, wherein the first electrode is a common electrode shared between the first transistor and the second transistor; and
a second memory cell over the interlayer dielectric.

14. The structure of claim 13, wherein the second transistor further comprises a third electrode on the interlayer dielectric, wherein the third electrode is a common electrode shared between the second transistor and the second memory cell.

15. The structure of claim 14, wherein the first memory cell comprises a fourth electrode partially overlapping a corner of the second electrode and the second memory cell comprises a fifth electrode partially overlapping a corner of the third electrode.

16. The structure of claim 15, wherein the first transistor comprises a first channel layer partially overlapping the second electrode and a first dielectric layer over the first channel layer, wherein the first dielectric layer is a common dielectric layer shared between the first transistor and the first memory cell.

17. The structure of claim 16, wherein the second transistor comprises a second channel layer partially overlapping the third electrode and a second dielectric layer over the second channel layer, wherein the second dielectric layer is a common dielectric layer shared between the second transistor and the second memory cell.

18. A method of forming a structure for a memory device, comprising:
forming an interlayer dielectric;
forming a first electrode in the interlayer dielectric;
forming a second electrode on the interlayer dielectric; and
forming a gate electrode partially in the interlayer dielectric and a third electrode on the interlayer dielectric, the gate electrode and the third electrode each partially overlap opposite corners of the second electrode.

19. The method of claim 18, further comprising forming a dielectric layer separating the gate electrode and the third electrode from the second electrode.

20. The method of claim 18, further comprising forming an opening through the gate electrode to form a two bit cell memory device.
